(19) United States
(12) Patent Application Publication
(10) Pub. No.: US 2017/0077056 A1
(43) Pub. Date: Mar. 16, 2017

(54) ANISOTROPIC CONDUCTIVE FILM AND PRODUCTION METHOD OF THE SAME

(71) Applicant: DEXERIALS CORPORATION, Tokyo (JP)

(72) Inventors: Reiji TSUKAO, Utsunomiya-shi (JP); Yasushi AKUTSU, Utsunomiya-shi (JP)

(73) Assignee: DEXERIALS CORPORATION, Tokyo (JP)

(21) Appl. No.: 15/116,033

(22) PCT Filed: Feb. 3, 2015
(86) PCT No.: PCT/JP15/52937

§ 371 Date: Aug. 2, 2016

(30) Foreign Application Priority Data
Feb. 4, 2014 (JP) 2014-019855
Feb. 4, 2014 (JP) 2014-019866

(51) Int. Cl. H01L 23/00; B32B 27/38; B32B 27/14

(52) U.S. Cl. CPC H01L 24/29; B32B 27/14; B32B 27/38; H01L 24/27; H01L 24/32; B32B 2307/202; B32B 2457/00; H01L 2224/29082; H01L 2224/2919; H01L 2924/0665; H01L 2224/27848; H01L 2924/2021; H01L 2224/29083; H01L 2224/32225; H01L 2924/14; H01L 2924/3511; H01L 2224/27003; H01L 2924/0635; H01L 2224/2929; H01L 2224/29355; H01L 2224/29357; H01L 2224/29339; H01L 2224/29347; H01L 2224/29344; H01L 2224/29364; H01L 2924/2064; H01L 2224/83101; H01L 2224/83851

(57) ABSTRACT

An anisotropic conductive film has a first connection layer and a second connection layer formed on a surface of the first connection layer. The first connection layer is a photopolymerized resin layer, and the second connection layer is a thermo- or photo-cationically, anionically, or radically polymerizable resin layer. Conductive particles for anisotropic conductive connection are arranged on a surface of the first connection layer on a side of the second connection layer so that the embedding ratio of the conductive particles in the first connection layer is 80% or more, or 1% or more and 20% or less.

### TECHNICAL FIELD

The present invention relates to an anisotropic conductive film and a production method of the same.

### BACKGROUND ART

An anisotropic conductive film has been widely used in mounting of electronic components such as an IC chip. In recent years, an anisotropic conductive film having a two-layer structure in which conductive particles for anisotropic conductive connection are arranged in a single layer on an insulating adhesion layer has been proposed (Patent Literature 1), in order to improve the conduction reliability and the insulating properties, increase the mounting conductive particle capture ratio, decrease the production cost, and the like from the viewpoints of application to high-density mounting.

This anisotropic conductive film having a two-layer structure is produced as follows. Conductive particles are arranged in a single layer and a close-packed state on a transfer layer, and then the transfer layer is biaxially stretched to form the transfer layer in which the conductive particles are uniformly arranged at predetermined intervals. After that, the conductive particles on the transfer layer are transferred into an insulating resin layer containing a thermosetting resin and a polymerization initiator, and another insulating resin layer containing a thermosetting resin and no polymerization initiator is laminated on the transferred conductive particles (Patent Literature 1).

### CITATION LIST

### Patent Literature

Patent Literature 1: Japanese Patent No. 4789738

### SUMMARY OF INVENTION

### Technical Problem

However, the insulating resin layer containing no polymerization initiator is used for the anisotropic conductive film having a two-layer structure in Patent Literature 1. Therefore, a comparatively large resin flow tends to occur in the insulating resin layer containing no polymerization initiator by heating during anisotropic conductive connection even with the conductive particles being uniformly arranged in a single layer at predetermined intervals. Along the resin flow, the conductive particles also tend to flow. Accordingly, there are problems of a decrease in mounting conductive particle capture ratio, occurrence of short circuit, a decrease in insulating properties, and the like.

An object of the present invention is to solve the problems in the conventional techniques, and to achieve favorable conduction reliability, favorable insulating properties, and favorable mounting conductive particle capture ratio in an anisotropic conductive film having a multilayer structure having conductive particles arranged in a single layer.

### Solution to Problem

The present inventors have found that an anisotropic conductive film obtained by arranging conductive particles in a single layer on a photopolymerizable resin layer so as to be embedded at a specific ratio, irradiating the photopolymerizable resin layer with ultraviolet light to fix or temporarily fix the conductive particles, and layering a thermo- or photo-cationically, anionically, or radically polymerizable resin layer on the fixed or temporarily fixed conductive particles has a constitution that can achieve the object of the present invention. As a result, the present invention has been accomplished.

Specifically, the present invention provides an anisotropic conductive film having a first connection layer and a second connection layer formed on a surface of the first connection layer, wherein the first connection layer is a photopolymerized resin layer, the second connection layer is a thermo- or photo-cationically, anionically, or radically polymerizable resin layer, and the first connection layer has conductive particles for anisotropic conductive connection that are arranged in a single layer on a surface on a side of the second connection layer, and the conductive particles are embedded in the first connection layer at an embedding ratio of 80% or more, or 1% or more and 20% or less. Herein, the embedding ratio means a degree of embedding of the conductive particles in the first connection layer, and can be defined as a ratio of the depth Lb of the conductive particles embedded in the first connection layer to the particle diameter La of the conductive particles. The embedding ratio can be determined by an equation “embedding ratio (%)=(Lb/La)×100.”

It is preferable that the second connection layer be a thermopolymerizable resin layer using a thermal polymerization initiator that initiates a polymerization reaction by heating. The second connection layer may be a photopolymerizable resin layer using a photopolymerization initiator that initiates a polymerization reaction by light. The second connection layer may be a thermo- and photo-polymerizable resin layer using a thermal polymerization initiator and a photopolymerization initiator in combination. Herein, the second connection layer may be restricted to a thermopolymerizable resin layer using a thermal polymerization initiator in terms of production.

The anisotropic conductive film of the present invention may have a third connection layer that has substantially the same constitution as that of the second connection layer on another surface of the first connection layer to prevent warping of a bonded body due to stress relaxation. Specifically, the first connection layer may have the third connection layer that includes a thermo- or photo-cationically, anionically, or radically polymerizable resin layer on the other surface thereof.

It is preferable that the third connection layer be a thermopolymerizable resin layer using a thermal polymerization initiator that initiates a polymerization reaction by heating. The third connection layer may be a photopolymerizable resin layer using a photopolymerization initiator that initiates a polymerization reaction by light. The third connection layer may be a thermo- and photo-polymerizable resin layer using a thermal polymerization initiator and a photopolymerization initiator in combination. Herein, the third connection layer may be restricted to a thermopolymerizable resin layer using a thermal polymerization initiator in terms of production.

The present invention provides a production method of the aforementioned anisotropic conductive film including the following steps (A) to (C) of forming the first connection layer by a photopolymerization reaction in a single step, or the following steps (AA) to (DD) of forming the first connection layer by a photopolymerization reaction in two steps.

### (When First Connection Layer is Formed by Photopolymerization Reaction in Single Step)

### Step (A)

A step of arranging conductive particles in a single layer on a photopolymerizable resin layer so that an embedding ratio of the conductive particles embedded in the first connection layer is 80% or more, or 1% or more and 20% or less;

### Step (B)

a step of irradiating the photopolymerizable resin layer having the arranged conductive particles with ultraviolet light to cause a photopolymerization reaction, to thereby form the first connection layer in which the conductive particles are fixed on the surface; and

### Step (C)

a step of forming the second connection layer that includes a thermo- or photo-cationically, anionically, or radically polymerizable resin layer on a surface of the first connection layer on the conductive particle side.

### (When First Connection Layer is Formed by Photopolymerization Reaction in Two Steps)

### Step (AA)

A step of arranging conductive particles in a single layer on a photopolymerizable resin layer so that an embedding ratio of the conductive particles embedded in the first connection layer is 80% or more, or 1% or more and 20% or less;

### Step (BB)

a step of irradiating the photopolymerizable resin layer having the arranged conductive particles with ultraviolet light to cause a photopolymerization reaction, to thereby form a first temporary connection layer in which the conductive particles are temporarily fixed on the surface;

### Step (CC)

a step of forming the second connection layer that includes a thermo-cationically, anionically, or radically polymerizable resin layer on a surface of the first temporary connection layer on the conductive particle side; and

### Step (DD)

a step of irradiating the first temporary connection layer with ultraviolet light from the second connection layer side and the opposite side thereof to cause a photopolymerization reaction, to thereby completely cure the first temporary connection layer to form the first connection layer.

In order not to affect the product life of the anisotropic conductive film, connection, and the stability of a connection structure, an initiator used in formation of the second connection layer at the step (CC) is restricted to a thermal polymerization initiator. Specifically, when the first connection layer is irradiated with ultraviolet light in two steps, the second connection layer may be restricted to a layer to be cured by thermal polymerization in terms of restriction of the step. When the irradiation with ultraviolet light in two steps is continuously performed, the first connection layer can be formed at the substantially same step as the step in the single step. Therefore, the same function effect can be expected.

The present invention provides a production method of the anisotropic conductive film having the third connection layer having the same constitution as that of the second connection layer on the other surface of the first connection layer, the production method having the following step (Z) after the step (C) in addition to the steps (A) to (C), or having the following step (Z) after the step (DD) in addition to the steps (AA) to (DD).

### Step (Z)

A step of forming the third connection layer that includes a thermo- or photo-cationically, anionically, or radically polymerizable resin layer on a surface of the first connection layer opposite to the conductive particles.

Further, the present invention provides a production method of the anisotropic conductive film having the third connection layer having substantially the same constitution as that of the second connection layer on the other surface of the first connection layer, the production method having the following step (a) before the step (A) in addition to the steps (A) to (C), or having the following step (a) before the step (AA) in addition to the steps (AA) to (DD).

### Step (a)

A step of forming the third connection layer that includes a thermo- or photo-cationically, anionically, or radically polymerizable resin layer on a surface of the photopolymerizable resin layer.

In the step (A) or (AA) in the production method having this step (a), the conductive particles may be arranged in a single layer on another surface of the photopolymerizable resin layer so that the embedding ratio of the conductive particles embedded in the first connection layer is 80% or more, or 1% or more and 20% or less.

When the third connection layer is provided in such a step, it is preferable that the polymerization initiator be restricted to an initiator that acts by a thermal reaction because of the above-described reason. However, when the second and third connection layers containing a photopolymerization initiator are provided by a method that does not affect the product life and connection after formation of the first connection layer, the production of the anisotropic conductive film containing the photopolymerization initiator in accordance with the main object of the present invention is not particularly restricted.

The present invention also encompasses an aspect in which the second or third connection layer of the present invention functions as a tacky layer.

The present invention further provides a connection structure in which a first electronic component and a second electronic component are connected by anisotropic conductive connection through the aforementioned anisotropic conductive film.

### Advantageous Effects of Invention

The anisotropic conductive film of the present invention has the first connection layer that includes a photopolymerized resin layer, and the second connection layer that includes a thermo- or photo-cationically, anionically, or radically polymerizable resin layer on a surface of the first connection layer, and has conductive particles for anisotropic conductive connection that are arranged in a single layer on the surface of the first connection layer on the second connection layer side so that the embedding ratio of the conductive particles in the first connection layer is 80% or more, or 1% or more and 20% or less. For this reason, the conductive particles can be securely fixed in the first connection layer. In particular, when the conductive particles are arranged in a single layer so that the embedding ratio is 80% or more, the conductive particles can be more tightly fixed in the first connection layer. Therefore, the bonding properties of the anisotropic conductive film is stably improved, and the productivity of the anisotropic conductive connection is improved. The photo-radically polymerizable resin layer under (on the back side of) the conductive particles in the first connection layer is not sufficiently irradiated with ultraviolet light due to the presence of the conductive particles. The curing ratio relatively decreases, and exhibits favorable pushing performance. As a result, favorable conduction reliability, insulating properties, and mounting conductive particle capture ratio can be achieved. When the conductive particles are arranged in a single layer so that the embedding ratio is 1% or more and 20% or less, the resin amount in the first connection layer does not largely decrease. Therefore, stickiness and adhesion strength can be enhanced.

When heat is used in anisotropic conductive connection, the anisotropic conductive connection is performed by the same method as a general method of connecting an anisotropic conductive film. When light is used, pushing by a connection tool may be performed by the end of a reaction. In this case, the connection tool or the like is often heated to promote resin flow and particle pushing. Even when heat and light are used in combination, the anisotropic conductive connection may be performed in the same manner as described above.

### BRIEF DESCRIPTION OF DRAWINGS

FIG. 1 is a cross-sectional view of an anisotropic conductive film of the present invention.

FIG. 2 is an explanatory diagram of a production step (A) of the anisotropic conductive film of the present invention.

FIG. 3A is an explanatory diagram of a production step (B) of the anisotropic conductive film of the present invention.

FIG. 3B is an explanatory diagram of the production step (B) of the anisotropic conductive film of the present invention.

FIG. 4A is an explanatory diagram of a production step (C) of the anisotropic conductive film of the present invention.

FIG. 4B is an explanatory diagram of the production step (C) of the anisotropic conductive film of the present invention.

FIG. 5 is a cross-sectional view of an anisotropic conductive film of the present invention.

FIG. 6 is an explanatory diagram of a production step (AA) of the anisotropic conductive film of the present invention.

FIG. 7A is an explanatory diagram of a production step (BB) of the anisotropic conductive film of the present invention.

FIG. 7B is an explanatory diagram of the production step (BB) of the anisotropic conductive film of the present invention.

FIG. 8A is an explanatory diagram of a production step (CC) of the anisotropic conductive film of the present invention.

FIG. 8B is an explanatory diagram of the production step (CC) of the anisotropic conductive film of the present invention.

FIG. 9A is an explanatory diagram of a production step (DD) of the anisotropic conductive film of the present invention.

FIG. 9B is an explanatory diagram of the production step (DD) of the anisotropic conductive film of the present invention.

### DESCRIPTION OF EMBODIMENTS

### <<Anisotropic Conductive Film>>

Hereinafter, a preferable example of the anisotropic conductive film of the present invention will be described in detail.

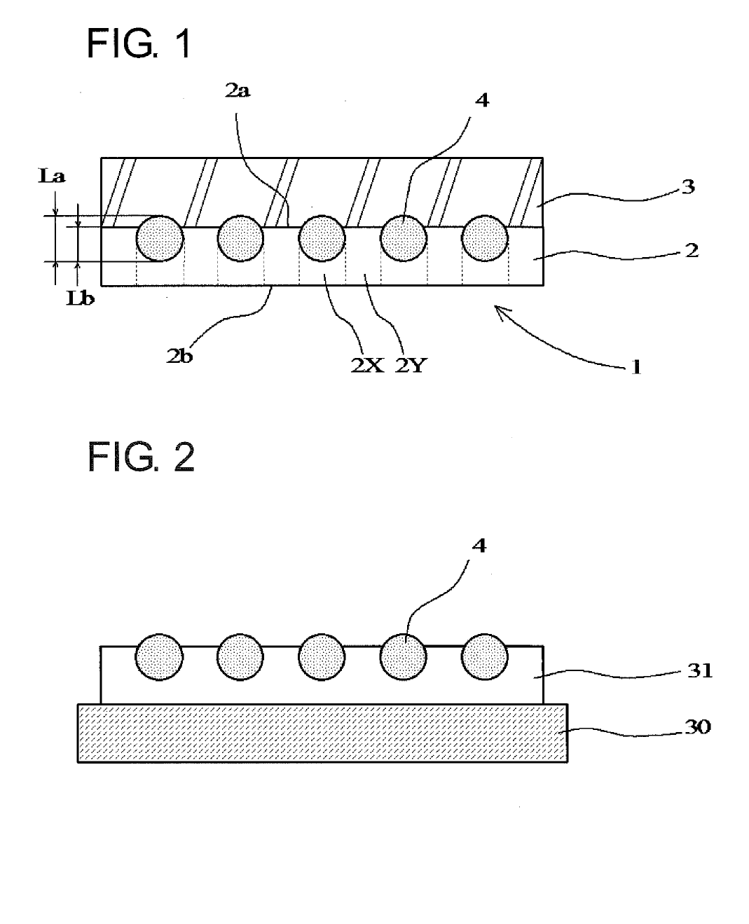

As shown in FIG. 1, an anisotropic conductive film 1 of the present invention has a constitution in which a second connection layer 3 that includes a thermo- or photo-cationically, anionically, or radically polymerizable resin layer is formed on a surface of a first connection layer 2 that includes a photopolymerized resin layer obtained by photopolymerizing a photopolymerizable resin layer. On a surface 2a of the first connection layer 2 on the side of the second connection layer 3, conductive particles 4 for anisotropic conductive connection are arranged in a single layer, and preferably uniformly arranged. The expression “uniformly” herein means a state where the conductive particles are arranged in a plane direction. This regularity may be defined as constant intervals.

### <First Connection Layer 2>

The first connection layer 2 constituting the anisotropic conductive film 1 of the present invention is a photopolymerized resin layer obtained by photopolymerizing a photopolymerizable resin layer such as a photo-cationically, anionically, or radically polymerizable resin layer. Therefore, the conductive particles can be fixed. Because of polymerization, the resin is unlikely to flow even under heating during anisotropic conductive connection. Therefore, the occurrence of short circuit can be largely suppressed. Accordingly, the conduction reliability and the insulating properties can be improved, and the mounting particle capture efficiency can be improved. It is particularly preferable that the first connection layer 2 be a photo-radically polymerized resin layer obtained by photo-radically polymerizing a photo-radically polymerizable resin layer containing an acrylate compound and a photo-radical polymerization initiator. Hereinafter, a case where the first connection layer 2 is a photo-radically polymerized resin layer will be described.

### (Acrylate Compound)

As an acrylate compound that is an acrylate unit, a conventionally known photo-radically polymerizable acrylate can be used. For example, a monofunctional (meth)acrylate (herein, (meth)acrylate includes acrylate and methacrylate), or a multifunctional (meth)acrylate having two or more functional groups can be used. In the present invention, in order to obtain a thermosetting adhesive, it is preferable that a multifunctional (meth)acrylate be used in at least a portion of acrylic monomers.

When the content of the acrylate compound in the first connection layer 2 is too small, a difference in viscosity between the first connection layer 2 and the second connection layer 3 is unlikely to be generated.

When the content thereof is too large, the curing shrinkage increases and the workability tends to decrease. Therefore, the content thereof is preferably 2 to 70% by mass, and more preferably 10 to 50% by mass.

### (Photo-Radical Polymerization Initiator)

As the photo-radical polymerization initiator, a publicly known photo-radical polymerization initiator can be appropriately selected and used. Examples of the publicly known photo-radical polymerization initiator may include an acetophenone-based photopolymerization initiator, a benzylketal-based photopolymerization initiator, and a phosphorus-based photopolymerization initiator.

When the amount of the photo-radical polymerization initiator to be used is too small relative to 100 parts by mass of the acrylate compound, photo-radical polymerization does not sufficiently proceed. When the amount is too large, stiffness may decrease. Therefore, the amount is preferably 0.1 to 25 parts by mass, and more preferably 0.5 to 15 parts by mass.

### (Conductive Particles)

As the conductive particles, conductive particles used in conventionally known anisotropic conductive films can be appropriately selected and used. Examples of the conductive particles may include metal particles such as nickel, cobalt, silver, copper, gold, and palladium particles, and metal-coated resin particles. Two or more kinds thereof may be used in combination.

When the average particle diameter of the conductive particles is too small, the variation of heights of wirings cannot be absorbed, and the resistance tends to increase. When the average particle diameter is too large, short circuit tends to occur. Therefore, the average particle diameter is preferably 1 to 10 μm, and more preferably 2 to 6 μm.

When the amount of such conductive particles in the first connection layer 2 is too small, the capture number of mounting conductive particles decreases, and the anisotropic conductive connection is difficult. When the amount is too large, short circuit may occur. Therefore, the amount is preferably 50 to 50,000, and more preferably 200 to 30,000 per square millimeter.

In the first connection layer 2, if necessary, a film-forming resin such as a phenoxy resin, an epoxy resin, an unsaturated polyester resin, a saturated polyester resin, a urethane resin, a butadiene resin, a polyimide resin, a polyamide resin, and a polyolefin resin can also be used in combination. In the second and third connection layers, the film-forming resin may also be used in combination, similarly.

When the thickness of the first connection layer 2 is too small, the mounting conductive particle capture ratio tends to decrease. When the thickness is too large, the conduction resistance tends to increase. Therefore, the thickness is preferably 1.0 to 6.0 μm, and more preferably 2.0 to 5.0 μm.

The first connection layer 2 may further contain an epoxy compound and a thermo- or photo-cationic or anionic polymerization initiator. In this case, it is preferable that the second connection layer 3 be also a thermo- or photo-cationically or anionically polymerizable resin layer containing an epoxy compound and a thermo- or photo-cationic or anionic polymerization initiator, as described below. Thus, the delamination strength can be improved. The epoxy compound and the thermo- or photo-cationic or anionic polymerization initiator will be described in relation to the second connection layer 3.

In the first connection layer 2, the conductive particles 4 are embedded in the first connection layer 2, as shown in FIG. 1. A degree of embedding is defined as a ratio (embedding ratio) of the depth Lb of the conductive particles 4 embedded in the first connection layer 2 to the particle diameter La of the conductive particles 4. The embedding ratio can be determined by an equation “embedding ratio (%)=(Lb/La)×100.”

In order to achieve an object in which “the conductive particles are fixed at intended positions to achieve favorable mounting conductive particle capture properties,” the embedding ratio of the conductive particles 4 in the first connection layer 2 in the present invention is adjusted to 80% or more, preferably 85% or more, and more preferably more than 90%. In this case, all parts of the conductive particles 4 may be embedded in the first connection layer 2, and preferably embedded so that the embedding ratio is 120% or less.

In order to achieve, in good balance, objects in which “the conductive particles are fixed at intended positions to achieve favorable mounting conductive particle capture properties,” and “the resin amount under the conductive particles is secured and favorable stickiness is achieved to enhance the adhesion strength between the first connection layer 2 and an adherend,” the lower limit of the embedding ratio of the conductive particles 4 in the first connection layer 2 in the present invention is adjusted to 1% or more, and preferably more than 1%, and the upper limit thereof is adjusted to 20% or less, and more preferably less than 20%.

The embedding ratio of the conductive particles 4 in the first connection layer 2 can be adjusted, for example, by repeatedly pressing the conductive particles by a rubber roller having a release material on the surface thereof. Specifically, in order to decrease the embedding ratio, the number of repeated processes is decreased. In order to increase the embedding ratio, the number of repeated processes is increased.

When the photopolymerizable resin layer is irradiated with ultraviolet light to form the first connection layer 2, any of a surface where the conductive particles are not disposed and a surface where the conductive particles are disposed may be irradiated. When the surface where the conductive particles are disposed is irradiated with ultraviolet light, the curing ratio of the first connection layer 2 in a region 2X of the first connection layer 2 between each of the conductive particles 4 and an outermost surface 2b of the first connection layer 2 can be made lower than that in a region 2Y of the first connection layer between the adjacent conductive particles 4. Thus, the region 2X of the first connection layer is likely to be eliminated during thermocompression-bonding of anisotropic conductive connection. Thus the conduction reliability is improved. The curing ratio herein represents a value defined as a decrease ratio of a vinyl group. The curing ratio of the region 2X of the first connection layer is preferably 40 to 80%, and the curing ratio of the region 2Y of the first connection layer is preferably 70 to 100%.

When the surface where the conductive particles are not disposed is irradiated, the curing ratios of the regions 2X and 2Y of the first connection layer is not substantially different. This is preferred in terms of quality of an ACF product. This is because the fixation of the conductive particles can proceed and stable quality can be secured at an ACF production process. Further, pressures applied to the arranged conductive particles at a winding start and a winding end can be made substantially the same under elongating the product in a general manner, and disordered arrangement can be prevented.

Photo-radical polymerization for formation of the first connection layer 2 may be performed in a single step (that is, by one irradiation with light), or in two steps (that is, by two-times irradiations with light). In this case, it is preferable that the second connection layer 3 be formed on the surface of the first connection layer 2 and another surface of the first connection layer 2 be then irradiated with light at the second step under an oxygen-containing atmosphere (in the air). As a result, a radical polymerization reaction is inhibited by oxygen to increase the surface concentration of an uncured component. Thus, an effect capable of improving the stickiness can be expected. Curing in two steps makes the polymerization reaction complex. Therefore, detailed control of fluidity of the resin and the particles can be expected.

In the region 2X of the first connection layer in such photo-radical polymerization in two steps, the curing ratio at the first step is preferably 10 to 50%, and the curing ratio at the second step is preferably 40 to 80%. In the region 2Y of the first connection layer, the curing ratio at the first step is preferably 30 to 90%, and the curing ratio at the second step is preferably 70 to 100%.

When a photo-radical polymerization reaction for formation of the first connection layer 2 is performed in two steps, only one kind of a radical polymerization initiator may be used. It is preferable, however, that two kinds of photo-radical polymerization initiators having different wavelength ranges that initiate a radical reaction be used in order to improve the stickiness. For example, it is preferable that a photo-radical polymerization initiator that initiates a radical reaction by light having a wavelength of 365 nm from an LED light source (for example, IRGACURE 369 available from BASF Japan Ltd.) and a photo-radical polymerization initiator that initiates a radical reaction by light from a light source of a high pressure mercury lamp (for example, IRGACURE 2959 available from BASF Japan Ltd.) be used in combination. When the two kinds of different photo-radical polymerization initiators are used, bonding of the resin is complicated. As a result, a behavior of thermal flow of the resin during connection can be finely controlled. This is because a force in a thickness direction tends to be applied to the particles and the flow of the particles in a plane direction is suppressed during pushing during anisotropic conductive connection. The effects of the present invention tend to be expressed.

The lowest melt viscosity of the first connection layer 2 measured by a rheometer is higher than that of the second connection layer 3. Specifically, a value of [the lowest melt viscosity of the first connection layer 2 (mPa·s)]/[the lowest melt viscosity of the second connection layer 3 (mPa·s)] is preferably 1 to 1,000, and more preferably 4 to 400. Among the lowest melt viscosities, the lowest melt viscosity of the former is preferably 100 to 100,000 mPa·s, and more preferably 500 to 50,000 mPa·s. The lowest melt viscosity of the latter is preferably 0.1 to 10,000 mPa·s, and more preferably 0.5 to 1,000 mPa·s.

The first connection layer 2 can be formed by attaching the conductive particles to the photo-radically polymerizable resin layer containing a photo-radically polymerizable acrylate and a photo-radical polymerization initiator by a procedure such as a film transferring method, a mold transferring method, an inkjet method, and an electrostatic attachment method and irradiating the photo-radically polymerizable resin layer with ultraviolet light from a side of the conductive particles, an opposite side thereof, or both the sides. It is preferable that the photo-radically polymerizable resin layer be irradiated with ultraviolet light from only the conductive particle side since the curing ratio of the region 2X of the first connection layer can be relatively decreased.

### <Second Connection Layer 3>

The second connection layer 3 includes a thermo- or photo-cationically, anionically, or radically polymerizable resin layer, and preferably includes a thermo- or photo-cationically or anionically polymerizable resin layer containing an epoxy compound and a thermo- or photo-cationic or anionic polymerization initiator, or a thermo- or photo-radically polymerizable resin layer containing an acrylate compound and a thermo- or photo-radical polymerization initiator. Herein, it is preferable that the second connection layer 3 be formed from the thermopolymerizable resin layer in terms of convenience of production and quality stability since a polymerization reaction does not occur in the second connection layer 3 by irradiation with ultraviolet light for formation of the first connection layer 2.

When the second connection layer 3 is the thermo- or photo-cationically or anionically polymerizable resin layer, the second connection layer 3 may further contain an acrylate compound and a thermo- or photo-radical polymerization initiator. Thus, the delamination strength between the first connection layer 2 and the second connection layer 3 can be improved.

### (Epoxy Compound)

When the second connection layer 3 is the thermo- or photo-cationically or anionically polymerizable resin layer containing an epoxy compound and a thermo- or photo-cationic or anionic polymerization initiator, examples of the epoxy compound may include a compound or a resin having two or more epoxy groups in the molecule. The compound and the resin may be liquid or solid.

### (Thermal Cationic Polymerization Initiator)

As the thermal cationic polymerization initiator, publicly known thermal cationic polymerization initiator for an epoxy compound can be used. For example, the thermal cationic polymerization initiator generates an acid, which can cationically polymerize a cationically polymerizable compound, by heat. A publicly known iodonium salt, sulfonium salt, phosphonium salt, ferrocenes, or the like can be used. An aromatic sulfonium salt that exhibits favorable latency for temperature can be preferably used.

When the amount of the thermal cationic polymerization initiator to be added is too small, curing tends to be difficult. When the amount is too large, the product life tends to be reduced. Therefore, the amount is preferably 2 to 60 parts by mass, and more preferably 5 to 40 parts by mass, relative to 100 parts by mass of the epoxy compound.

### (Thermal Anionic Polymerization Initiator)

As the thermal anionic polymerization initiator, a publicly known thermal anionic polymerization initiator for an epoxy compound can be used. For example, the thermal anionic polymerization initiator generates a base, which can anionically polymerize an anionically polymerizable compound, by heat. A publicly known aliphatic amine-based compound, aromatic amine-based compound, secondary or tertiary amine-based compound, imidazole-based compound, polymercaptan-based compound, boron trifluoride-amine complex, dicyandiamide, organic acid hydrazide, or the like can be used. An encapsulated imidazole-based compound that exhibits favorable latency for temperature can be preferably used.

When the amount of the thermal anionic polymerization initiator to be added is too small, curing tends to be difficult. When the amount is too large, the product life tends to be reduced. Therefore, the amount is preferably 2 to 60 parts by mass, and more preferably 5 to 40 parts by mass, relative to 100 parts by mass of the epoxy compound.

### (Photo-Cationic Polymerization Initiator and Photo-Anionic Polymerization Initiator)

As the photo-cationic polymerization initiator or the photo-anionic polymerization initiator for an epoxy compound, a publicly known polymerization initiator can be appropriately used.

### (Acrylate Compound)

When the second connection layer 3 is the thermo- or photo-radically polymerizable resin layer containing an acrylate compound and a thermo- or photo-radical polymerization initiator, the acrylate compound described in relation to the first connection layer 2 can be appropriately selected and used.

### (Thermal Radical Polymerization Initiator)

Examples of the thermal radical polymerization initiator may include an organic peroxide and an azo-based compound. An organic peroxide that does not generate nitrogen causing bubbles can be preferably used.

When the amount of the thermal radical polymerization initiator to be used is too small, curing is difficult. When the amount is too large, the product life is reduced. Therefore, the amount is preferably 2 to 60 parts by mass, and more preferably 5 to 40 parts by mass, relative to 100 parts by mass of the acrylate compound.

### (Photo-Radical Polymerization Initiator)

As the photo-radical polymerization initiator for an acrylate compound, a publicly known photo-radical polymerization initiator can be used.

When the amount of the photo-radical polymerization initiator to be used is too small, curing is difficult. When the amount is too large, the product life is reduced. Therefore, the amount is preferably 2 to 60 parts by mass, and more preferably 5 to 40 parts by mass, relative to 100 parts by mass of the acrylate compound.

### (Third Connection Layer 5)

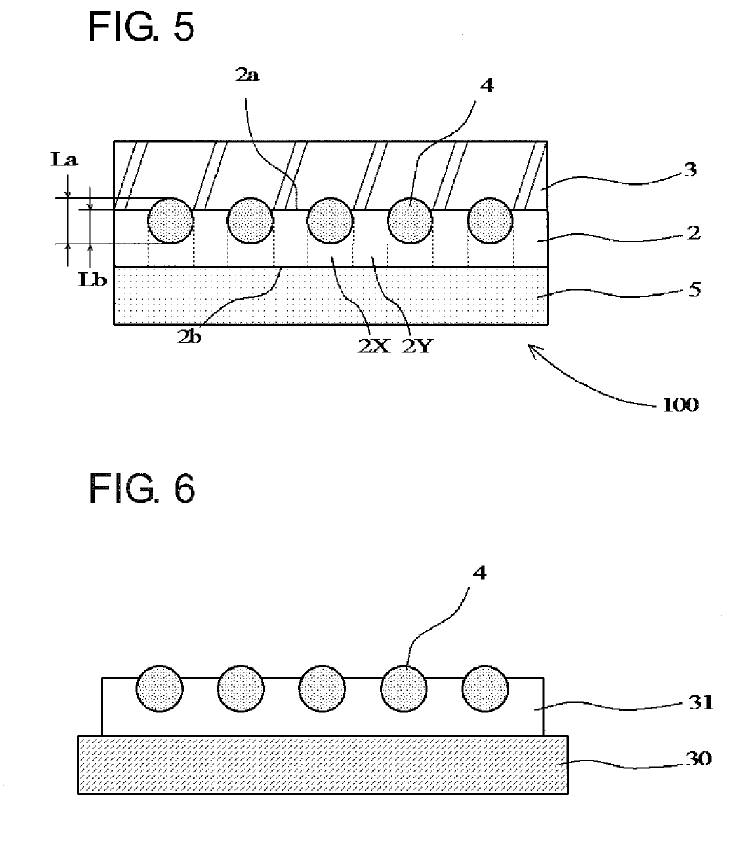

The anisotropic conductive film having a two-layer structure in FIG. 1 is described above. As shown in FIG. 5, a third connection layer 5 may be formed on another surface of the first connection layer 2. Thus, an effect capable of finely controlling the fluidity of the whole layer can be obtained. Herein, the third connection layer 5 may have the same constitution as that of the second connection layer 3. Specifically, the third connection layer 5 includes a thermo- or photo-cationically or anionically polymerizable resin layer (preferably a polymerizable resin layer containing an epoxy compound and a thermo- or photo-cationic or anionic polymerization initiator), or a thermo- or photo-radically polymerizable resin layer (preferably a polymerizable resin layer containing an acrylate compound and a thermo- or photo-radical polymerization initiator). After the second connection layer is formed on a surface of the first connection layer, such a third connection layer 5 may be formed on another surface of the first connection layer. Alternatively, before formation of the second connection layer, the third connection layer may be formed in advance on another surface (where the second connection layer is not formed) of the first connection layer or the photopolymerizable resin layer as a precursor.

### <<Production Method of Anisotropic Conductive Film>>

The production method of the anisotropic conductive film of the present invention includes a production method that performs a photopolymerization reaction in a single step and a production method that performs a photopolymerization reaction in two steps.

<Production Method that Performs Photopolymerization Reaction in Single Step>

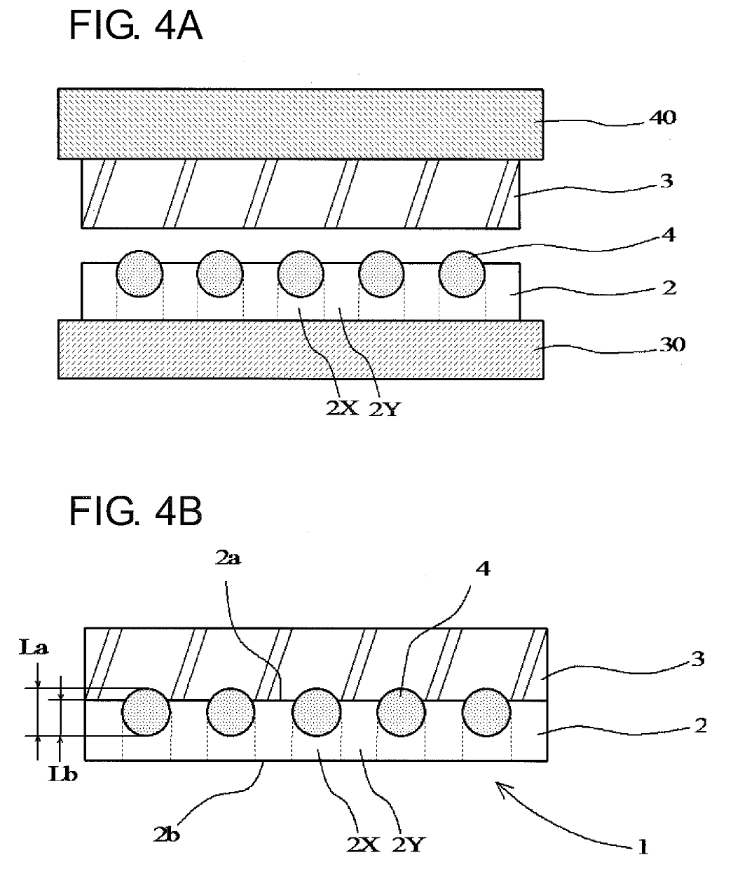

One example in which the anisotropic conductive film of FIG. 1 (FIG. 4B) is produced by photopolymerization in a single step will be described. This production example includes the following steps (A) to (C).

### (Step (A))

As shown in FIG. 2, the conductive particles 4 are arranged in a single layer on a photopolymerizable resin layer 31 that is formed on a release film 30, if necessary, so that the embedding ratio is 80% or more, or 1% or more and 20% or less. A procedure of arranging the conductive particles 4 is not particularly limited. A method using a biaxial stretching operation for an unstretched polypropylene film in Example 1 of Japanese Patent No. 4789738, a method using a mold in Japanese Patent Application Laid-Open No. 2010-33793, or other methods may be used. For the degree of arrangement, the size, conduction reliability, insulating properties, mounting conductive particle capture ratio of a connection subject, and the like are taken in account. The conductive particles are preferably arranged so as to be two-dimensionally apart about 1 to about 100 μm from each other.

The embedding ratio can be adjusted by repeatedly pressing the conductive particles by an elastic body such as a rubber roller.

### (Step (B))

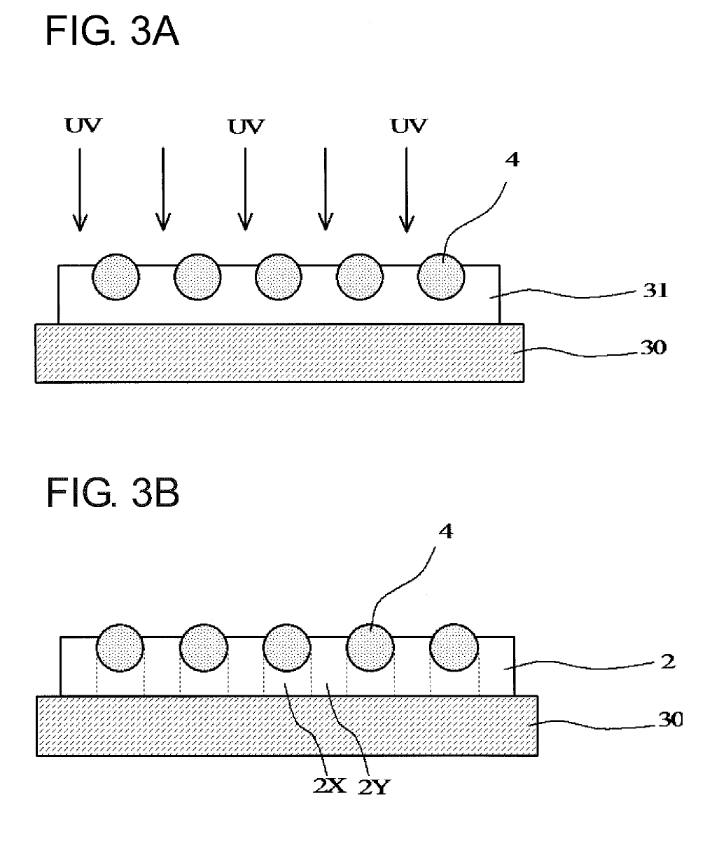

As shown in FIG. 3A, the photopolymerizable resin layer 31 having the arranged conductive particles 4 is irradiated with ultraviolet light (UV) to cause a photopolymerization reaction, so that the first connection layer 2 in which the conductive particles 4 are fixed on the surface is formed. In this case, the photopolymerizable resin layer may be irradiated with ultraviolet light (UV) from the side of the conductive particles, or from the opposite side. When the photopolymerizable resin layer is irradiated with ultraviolet light (UV) from the side of the conductive particles, the curing ratio of the region 2X of the first connection layer between each of the conductive particles 4 and the outermost surface of the first connection layer 2 can be made lower than that of the region 2Y of the first connection layer between adjacent conductive particles 4, as shown in FIG. 3B. Thus, the curing properties of back side of the particles are surely reduced to facilitate pushing during bonding. In addition, an effect of preventing the flow of the particles can also be obtained.

### (Step (C))

As shown in FIG. 4A, the second connection layer 3 that includes a thermo- or photo-cationically, anionically, or radically polymerizable resin layer is formed on a surface of the first connection layer 2 on a side of the conductive particles 4. Specifically, the second connection layer 3 formed by an ordinary method on a release film 40 is placed on the surface of the first connection layer 2 on the side of the conductive particles 4 and thermocompression-bonding is performed so as not to cause excess thermal polymerization. The release films 30 and 40 are removed. Thus, an anisotropic conductive film of FIG. 4B can be obtained.

An anisotropic conductive film 100 of FIG. 5 can be obtained by performing the following step (Z) after the step (C).

### (Step (Z))

The third connection layer that includes a thermo- or photo-cationically, anionically, or radically polymerizable resin layer is formed on a surface of the first connection layer opposite to the conductive particles, preferably like the second connection layer. Thus, the anisotropic conductive film of FIG. 5 can be obtained.

The anisotropic conductive film 100 of FIG. 5 can be obtained by performing the following step (a) before the step (A) without performing the step (z).

### (Step (a))

This step is a step of forming the third connection layer that includes a thermo- or photo-cationically, anionically, or radically polymerizable resin layer on a surface of the photopolymerizable resin layer. After this step (a), the anisotropic conductive film 100 of FIG. 5 can be obtained by performing the steps (A), (B), and (C). At the step (A), however, the conductive particles are arranged in a single layer on another surface of the photopolymerizable resin layer so that the embedding ratio is 80% or more, or 1% or more and 20% or less.

(Production Method that Performs Photopolymerization Reaction in Two Steps)

One example in which the anisotropic conductive film of FIG. 1 (FIG. 4B) is produced by photopolymerization in two steps will be described. This production example includes the following steps (AA) to (DD).

### (Step (AA))

As shown in FIG. 6, the conductive particles 4 are arranged in a single layer on the photopolymerizable resin layer 31 that is formed on the release film 30, if necessary, so that the embedding ratio is 80% or more, or 1% or more and 20% or less. A procedure of arranging the conductive particles 4 is not particularly limited. The method using a biaxial stretching operation for an unstretched polypropylene film in Example 1 of Japanese Patent No. 4789738, the method using a mold in Japanese Patent Application Laid-Open No. 2010-33793, or other methods may be used. For the degree of arrangement, the size, conduction reliability, insulating properties, mounting conductive particle capture ratio of a connection subject, and the like are taken in account. The conductive particles are preferably arranged so as to be two-dimensionally apart about 1 to about 100 μm from each other.

### (Step (BB))

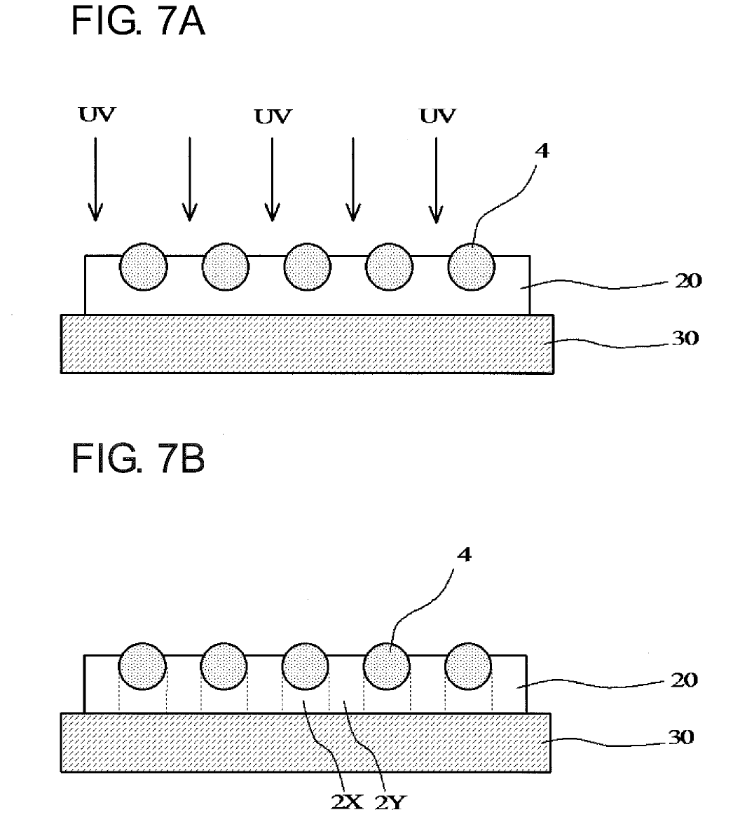

As shown in FIG. 7A, the photopolymerizable resin layer 31 having the arranged conductive particles 4 is irradiated with ultraviolet light (UV) to cause a photopolymerization reaction, so that a first temporary connection layer 20 in which the conductive particles 4 are temporarily fixed on the surface is formed. In this case, the photopolymerizable resin layer may be irradiated with ultraviolet light (UV) from the side of the conductive particles, or from the opposite side. When the photopolymerizable resin layer is irradiated with ultraviolet light (UV) from the side of the conductive particles, the curing ratio of the region 2X of the first connection layer between each of the conductive particles 4 and the outermost surface of the first temporary connection layer 20 can be made lower than that of the region 2Y of the first connection layer between the adjacent conductive particles 4, as shown in FIG. 7B.

### (Step (CC))

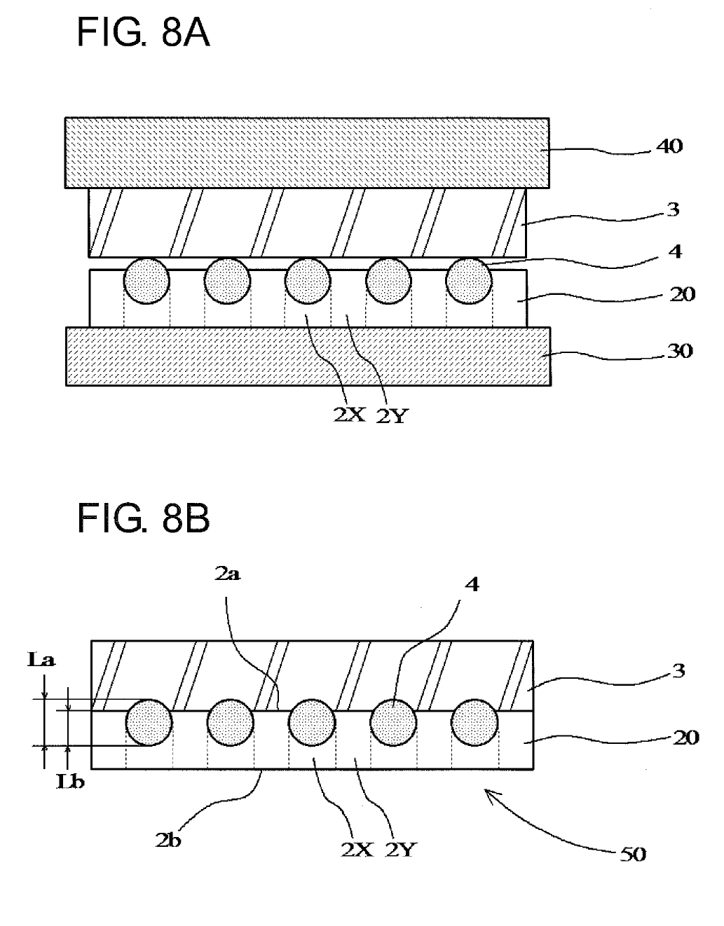

As shown in FIG. 8A, the second connection layer 3 that includes a thermo-cationically, anionically, or radically polymerizable resin layer is formed on a surface of the first temporary connection layer 20 on a side of the conductive particles 4. Specifically, the second connection layer 3 formed by an ordinary method on the release film 40 is disposed on the surface of the first connection layer 2 on the side of the conductive particles 4 and thermocompression-bonding is performed so as not to cause excess thermal polymerization. The release films 30 and 40 are removed. Thus, a temporary anisotropic conductive film 50 of FIG. 8B can be obtained.

### (Step (DD))

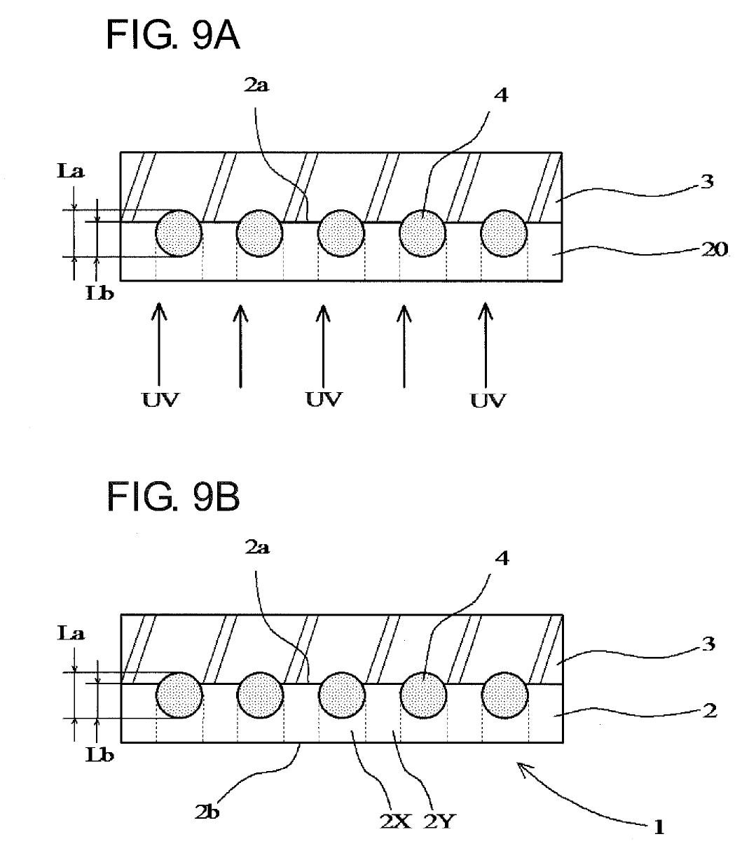

As shown in FIG. 9A, the first temporary connection layer 20 is irradiated with ultraviolet light from the side opposite to the second connection layer 3 to cause a photopolymerization reaction, so that the first temporary connection layer 20 is fully cured to form the first connection layer 2. Thus, an anisotropic conductive film 1 of FIG. 9B can be obtained. At this step, it is preferable that the first temporary connection layer be irradiated ultraviolet light in a direction perpendicular to the first temporary connection layer. In order not to eliminate a difference in curing ratio between the regions 2X and 2Y of the first connection layer, it is preferable that irradiation be performed through a mask or a difference in amount of irradiated light be produced depending on an irradiated portion.

When the photopolymerization is caused in two steps, the anisotropic conductive film 100 of FIG. 5 can be obtained by performing the following step (Z) after the step (DD).

### (Step (Z))

The third connection layer that includes a thermally or photo-cationically, anionically, or radically polymerizable resin layer is formed on a surface of the first connection layer opposite to the conductive particles, preferably like the second connection layer. Thus, the anisotropic conductive film of FIG. 5 can be obtained.

The anisotropic conductive film 100 of FIG. 5 can be obtained by performing the following step (a) before the step (AA) without performing the step (Z).

### (Step (a))

This step is a step of forming the third connection layer that includes a thermo- or photo-cationically, anionically, or radically polymerizable resin layer on a surface of the photopolymerizable resin layer. The anisotropic conductive film 100 of FIG. 5 can be obtained by performing the steps (AA) to (DD) after this step (a). At the step (AA), the conductive particles are arranged in a single layer on another surface of the photopolymerizable resin layer so that the embedding ratio is 80% or more, or 1% or more and 20% or less. In this case, it is preferable that the polymerization initiator used for formation of the second connection layer be a thermal polymerization initiator. Use of a photopolymerization initiator may affect the product life of the anisotropic conductive film, connection, and the stability of a connection structure in terms of the steps.

### <<Connection Structure>>

The anisotropic conductive film thus obtained can be preferably applied to anisotropic conductive connection between a first electronic component such as an IC chip and an IC, module and a second electronic component such as a flexible substrate and a glass substrate. The resultant connection structure is also a part of the present invention. It is preferable that a surface of the anisotropic conductive film on the side of the first connection layer be disposed on a side of the second electronic component such as a flexible substrate and a surface of the anisotropic conductive film on the side of the second connection layer be disposed on a side of the first electronic component such as an IC chip since the conduction reliability is enhanced.

### EXAMPLES

Hereinafter, the present invention will be described specifically by Examples.

### Examples 1 to 6 and Comparative Example 1

Conductive particles were arranged in accordance with an operation of Example 1 of Japanese Patent No. 4789738, and an anisotropic conductive film having a two-layer structure in which first and second connection layers were layered in accordance with a composition (parts by mass) of Table 1 was produced.

### (First Connection Layer)

Specifically, an acrylate compound, a photo-radical polymerization initiator, and others were mixed in ethyl acetate or toluene to prepare a mixed liquid having a solid content of 50% by mass. This mixed liquid was applied to a polyethylene terephthalate film having a thickness of 50 μm so as to have a dried thickness of 5 μm, and dried in an oven at 80° C. for 5 minutes, to form a photo-radically polymerizable resin layer that was a precursor of the first connection layer.

Conductive particles (Ni/Au-plated resin particles, AUL 704, available from SEKISUI CHEMICAL CO., LTD.) having an average particle diameter of 4 μm were arranged at intervals of 4 μm in a single layer on the obtained photo-radically polymerizable resin layer by adjusting the number of repeated pressing processes by a rubber roller so that the embedding ratio of the conductive particles in the first connection layer was a percentage shown in Table 1 with respect to the particle diameter. The photo-radically polymerizable resin layer was irradiated with ultraviolet light having a wavelength of 365 nm and an integrated light amount of 4,000 mJ/cm² from the conductive particle side. Thus, the first connection layer in which the conductive particles were fixed on the surface was formed.

### (Second Connection Layer)

A thermosetting resin, a latent curing agent, and others were mixed in ethyl acetate or toluene to prepare a mixed liquid having a solid content of 50% by mass. This mixed liquid was applied to a polyethylene terephthalate film having a thickness of 50 μm so as to have a dried thickness of 12 μm, and dried in an oven at 80° C. for 5 minutes, to form the second connection layer.

### (Anisotropic Conductive Film)

The thus obtained first and second connection layers were laminated so that the conductive particles were located inside, to obtain the anisotropic conductive film.

### (Connection Structure Sample)

An IC chip having a size of 0.5×1.8×20.0 mm (bump size: 30×85 μm, bump height: 15 μm, bump pitch: 50 μm) was mounted on a glass wiring substrate (1737F) having a size of 0.5×50×30 mm available from Corning Incorporated using the obtained anisotropic conductive film under conditions of 180° C., 80 MPa, and 5 seconds to obtain a connection structure sample.

### (Test Evaluation)

As described below, “mounting conductive particle capture ratio,” “conduction reliability,” “number of linked particles,” and “insulating properties” of the anisotropic conductive film in the obtained connection structure sample were tested and evaluated. Table 1 shows the obtained results.

An IC chip having a size of 0.5×1.5×13 mm (gold-plated bump size: 25×140 μm, bump height: 15 μm, space between bumps: 7.5 μm) was mounted on a glass wiring substrate (1737F) having a size of 0.5×50×30 mm available from Corning Incorporated under conditions of 180° C., 80 MPa, and 5 seconds to obtain a connection structure sample. The connection structure sample was used in evaluation of “insulating properties.”

### “Mounting Conductive Particle Capture Ratio”

The ratio of the “amount of particles actually captured on the bump of the connection structure sample after heating and pressurization (after actual mounting)” to the “theoretical amount of particles existing on the bump of the connection structure sample before heating and pressurization” was determined in accordance with the following mathematical expression.

Mounting Conductive Particle Capture Ratio (%)={[the number of conductive particles on bump after heating and pressurization]/[the number of conductive particles on bump before heating and pressurization]}×100

### “Conduction Reliability”

The connection structure sample was left under a high-temperature and high-humidity environment of 85° C. and 85% RH for 500 hours. The conduction resistance was measured by a digital multimeter (Agilent Technologies). For practical use, the conduction resistance is desirably 4Ω or less.

### “Number of Linked Particles”

A 10-mm square region of the obtained connection structure sample was observed by an electron microscope at a magnification of 50 times. A linked body in which two or more conductive particles were linked in a linear or lump shape was taken as one linked particle. The number of the linked particle was counted. For example, when the number of linked particles in which two conductive particles are linked is two and the number of linked particles in which four conductive particles are linked is one, the number of the linked particles is three. When the number of the linked particles increases, the number of conductive particles constituting the linked particles tends to increase. Therefore, the independence of the conductive particles existing in a space between the bumps tends to be deteriorated, and the occurrence probability of short circuit tends to increase.

### “Insulating Properties (Occurrence Ratio of Short Circuit)”

The short circuit occurrence ratio of a comb-teeth TEG pattern having a space of 7.5 μm was determined. For practical use, the ratio is desirably 100 ppm or less.

TABLE 1

| | | | | Example | | | |
|---|---|---|---|---|---|---|---|
| | | | | 1 | 2 | 3 | 4 |
| First Connection | Phenoxy Resin | YP-50 | Nippon Steel & Sumitomo Metal | 60 | 60 | 60 | 60 |
| Layer | | | Corporation | | | | |
| | Acrylate | EB600 | Daicel-Allnex Ltd. | 40 | 40 | 40 | 40 |
| | Photo-Radical | IRGACURE 369 | BASF Japan Ltd. | 2 | 2 | 2 | 2 |
| | Polymerization | | | | | | |
| | Initiator | | | | | | |
| | Thermal Cationic | SI-60L | Sanshin Chemical Industry Co., Ltd. | 2 | 2 | 2 | 2 |
| | Polymerization | | | | | | |
| | Initiator | | | | | | |
| | Conductive Particle | AUL704 | Sekisui Chemical Co., Ltd. | Uniform | Uniform | Uniform | Uniform |
| | Arrangement | | | | | | |
| Second | Phenoxy Resin | YP-50 | Nippon Steel & Sumitomo Metal | 60 | 60 | 60 | 60 |
| Connection Layer | | | Corporation | | | | |
| | Epoxy Resin | jER828 | Mitsubishi Chemical Corporation | 40 | 40 | 40 | 40 |
| | Thermal Cationic | SI-60L | Sanshin Chemical Industry Co., Ltd. | 2 | 2 | 2 | 2 |
| | Polymerization | | | | | | |
| | Initiator | | | | | | |

| | | | | |
|---|---|---|---|---|
| Embedding Ratio Of Conductive Particles In First Connection Layer (%) | 80.2 | 85 | 90.2 | 95 |
| Mounting Conductive Particle Capture Ratio (%) | 82 | 84 | 85 | 88 |
| Conduction Reliability (Ω) | 4 | 4 | 4 | 4 |
| Number Of Linked Particles | 10 | 10 | 9 | 8 |
| Short Circuit Occurrence Rate (ppm) | 20 | 20 | 20 | 20 |

| | | | | | | Comparative |
|---|---|---|---|---|---|---|
| | | | | Example | | Example |
| | | | | 5 | 6 | 1 |
| First Connection | Phenoxy Resin | YP-50 | Nippon Steel & Sumitomo Metal | 60 | 60 | 60 |
| Layer | | | Corporation | | | |
| | Acrylate | EB600 | Daicel-Allnex Ltd. | 40 | 40 | 40 |
| | Photo-Radical | IRGACURE 369 | BASF Japan Ltd. | 2 | 2 | 2 |
| | Polymerization | | | | | |
| | Initiator | | | | | |
| | Thermal Cationic | SI-60L | Sanshin Chemical Industry Co., Ltd. | 2 | 2 | 2 |
| | Polymerization | | | | | |
| | Initiator | | | | | |
| | Conductive Particle | AUL704 | Sekisui Chemical Co., Ltd. | Uniform | Uniform | Uniform |
| | Arrangement | | | | | |
| Second | Phenoxy Resin | YP-50 | Nippon Steel & Sumitomo Metal | 60 | 60 | 60 |
| Connection Layer | | | Corporation | | | |
| | Epoxy Resin | jER828 | Mitsubishi Chemical Corporation | 40 | 40 | 40 |
| | Thermal Cationic | SI-60L | Sanshin Chemical Industry Co., Ltd. | 2 | 2 | 2 |
| | Polymerization | | | | | |
| | Initiator | | | | | |

| | | | |
|---|---|---|---|
| Embedding Ratio Of Conductive Particles In First Connection Layer (%) | 99 | 105 | 75 |
| Mounting Conductive Particle Capture Ratio (%) | 90 | 90 | 80 |
| Conduction Reliability (Ω) | 4 | 4 | 4 |
| Number Of Linked Particles | 5 | 5 | 24 |
| Short Circuit Occurrence Rate (ppm) | 20 | 20 | 50 |

As seen from Table 1, in the anisotropic conductive films of Examples 1 to 6, the embedding ratio of conductive particles in the first connection layer was 80% or more, and the number of linked particles was 10 or less. In all evaluation items of mounting conductive particle capture ratio, conduction reliability, and short circuit occurrence ratio, preferable effects in practical terms were exhibited.

On the other hand, in the anisotropic conductive film of Comparative Example 1, the embedding ratio of conductive particles in the first connection layer was 75% that was less than 80%. Therefore, the number of linked particles increased, and the short circuit occurrence ratio increased to 50 ppm.

### Example 7

An anisotropic conductive film was formed in the same manner as in Example 1 except that a photo-radically polymerizable resin layer was irradiated with ultraviolet light at an integrated light amount of 2,000 mJ/cm² in formation of a first connection layer. Further, a surface of the anisotropic conductive film on the first connection layer side was irradiated with ultraviolet light having a wavelength of 365 nm at an integrated light amount of 2,000 mJ/cm² to obtain the anisotropic conductive film of Example 7 in which both surfaces of the first connection layer were irradiated with ultraviolet light. A connection structure sample was formed using this anisotropic conductive film and evaluated in the same manner as in the case of the anisotropic conductive film of Example 1. Substantially the same results without problems in practical terms were obtained, but the mounting conductive particle capture ratio tended to be further improved.

### Examples 8 to 12 and Comparative Examples 2 and 3

An anisotropic conductive film was obtained by repeating the same operation as in Example 1 except that conductive particles were arranged in a single layer by adjusting the number of repeated pressing processes by a rubber roller so that the embedding ratio of the conductive particles in the first connection layer was a percentage shown in Table 2 with respect to the particle diameter. A connection structure sample was then obtained.

### (Test Evaluation)

In the same manner as in Example 1, “mounting conductive particle capture ratio,” “conduction reliability,” and “insulating properties (short circuit occurrence ratio)” of the anisotropic conductive films in the obtained connection structure samples were tested and evaluated. As described below, ““sticky force” on the first connection layer side” and “adhesion strength (die shear)” were further tested and evaluated. Table 2 shows the obtained results.

TABLE 2

| | | | | Example | | | |
|---|---|---|---|---|---|---|---|
| | | | | 8 | 9 | 10 | 11 |
| First Connection | Phenoxy Resin | YP-50 | Nippon Steel & Sumitomo Metal | 60 | 60 | 60 | 60 |
| Layer | | | Corporation | | | | |
| | Acrylate | EB600 | Daicel-Allnex Ltd. | 40 | 40 | 40 | 40 |
| | Photo-Radical | IRGACURE 369 | BASF Japan Ltd. | 2 | 2 | 2 | 2 |
| | Polymerization | | | | | | |
| | Initiator | | | | | | |
| | Thermal | SI-60L | Sanshin Chemical Industry Co., Ltd. | 2 | 2 | 2 | 2 |
| | Cationic Polymerization | | | | | | |
| | Initiator | | | | | | |
| | Conductive Particle | AUL704 | Sekisui Chemical Co., Ltd. | Uniform | Uniform | Uniform | Uniform |
| | Arrangement | | | | | | |
| Second | Phenoxy Resin | YP-50 | Nippon Steel & Sumitomo Metal | 60 | 60 | 60 | 60 |
| Connection Layer | | | Corporation | | | | |
| | Epoxy Resin | jER828 | Mitsubishi Chemical Corporation | 40 | 40 | 40 | 40 |
| | Thermal Cationic | SI-60L | Sanshin Chemical Industry Co., Ltd. | 2 | 2 | 2 | 2 |
| | Polymerization Initiator | | | | | | |

| | | | | |
|---|---|---|---|---|
| Embedding Ratio Of Conductive Particles In First Connection Layer (%) | 19.9 | 15 | 9.9 | 3 |
| Sticky Force (kPa) | 12 | 14 | 15 | 16 |
| Adhesion Strength (Die Shear) (N) | 1200 | 1250 | 1300 | 1400 |
| Mounting Conductive Particle Capture Ratio (%) | 80< | 80< | 80< | 80< |
| Conduction Reliability (Ω) | 4 | 4 | 4 | 4 |
| Short Circuit Occurrence Rate (ppm) | 20 | 20 | 20 | 20 |

| | | | | Example | Comparative Example | |
|---|---|---|---|---|---|---|
| | | | | 12 | 2 | 3 |
| First Connection | Phenoxy Resin | YP-50 | Nippon Steel & Sumitomo Metal | 60 | 60 | 60 |
| Layer | | | Corporation | | | |
| | Acrylate | EB600 | Daicel-Allnex Ltd. | 40 | 40 | 40 |
| | Photo-Radical | IRGACURE 369 | BASF Japan Ltd. | 2 | 2 | 2 |
| | Polymerization | | | | | |
| | Initiator | | | | | |
| | Thermal | SI-60L | Sanshin Chemical Industry Co., Ltd. | 2 | 2 | 2 |
| | Cationic Polymerization | | | | | |
| | Initiator | | | | | |
| | Conductive Particle | AUL704 | Sekisui Chemical Co., Ltd. | Uniform | Uniform | Uniform |
| | Arrangement | | | | | |
| Second | Phenoxy Resin | YP-50 | Nippon Steel & Sumitomo Metal | 60 | 60 | 60 |
| Connection Layer | | | Corporation | | | |
| | Epoxy Resin | jER828 | Mitsubishi Chemical Corporation | 40 | 40 | 40 |
| | Thermal Cationic | SI-60L | Sanshin Chemical Industry Co., Ltd. | 2 | 2 | 2 |
| | Polymerization Initiator | | | | | |

| | | | |
|---|---|---|---|
| Embedding Ratio Of Conductive Particles In First Connection Layer (%) | 1 | 25 | 0.5 |
| Sticky Force (kPa) | 20 | 10 | 20 |
| Adhesion Strength (Die Shear) (N) | 1500 | 1100 | 1500 |
| Mounting Conductive Particle Capture Ratio (%) | 80< | 80 | 60 |
| Conduction Reliability (Ω) | 4 | 4 | 20 |
| Short Circuit Occurrence Rate (ppm) | 20 | 50 | 150 |

As seen from Table 2, for the anisotropic conductive films of Examples 8 to 12, the embedding ratio of conductive particles in the first connection layer was 1% or more and 20% or less. In all evaluation items of sticky force, adhesion strength, mounting conductive particle capture ratio, conduction reliability, and insulating properties (short circuit occurrence ratio), preferable effects in practical terms were exhibited.

On the other hand, in the anisotropic conductive film of Comparative Example 2, the embedding ratio of conductive particles in the first connection layer exceeded 20%. Therefore, the sticky force and adhesion strength of this anisotropic conductive film were lower than those of the anisotropic conductive films of Examples 8 to 12. The short circuit occurrence ratio increased about 2.5 times. In the anisotropic conductive film of Comparative Example 3, the embedding ratio of conductive particles in the first connection layer was less than 1%. Therefore, the mounting conductive particle capture ratio of this anisotropic conductive film was lower than those of the anisotropic conductive films of Examples 8 to 12. The short circuit occurrence ratio that was an evaluation index of insulating properties increased about 7.5 times.

### Example 13

An anisotropic conductive film was formed in the same manner as in Example 8 except that a photo-radically polymerizable resin layer was irradiated with ultraviolet light at an integrated light amount of 2,000 mJ/cm² in formation of a first connection layer. Further, a surface of the anisotropic conductive film on the first connection layer side was irradiated with ultraviolet light having a wavelength of 365 nm at an integrated light amount of 2,000 mJ/cm² to obtain the anisotropic conductive film of Example 13 in which both surfaces of the first connection layer were irradiated with ultraviolet light. A connection structure sample was formed using the anisotropic conductive film and evaluated in the same manner as in the case of the anisotropic conductive film of Example 8. Substantially the same results without problems in practical terms were obtained, but the mounting conductive particle capture ratio tended to be further improved.

### INDUSTRIAL APPLICABILITY

The anisotropic conductive film of the present invention has a two-layer structure in which a first connection layer that includes a photopolymerized resin layer and a second connection layer that includes a thermo- or photo-cationically or anionically polymerizable resin layer, or a thermo- or photo-radically polymerizable resin layer, and conductive particles for anisotropic conductive connection that are arranged in a single layer on a surface of the first connection layer on a side of the second connection layer so that the embedding ratio in the first connection layer is 80% or more. For this reason, the conductive particles can be favorably fixed in the first connection layer. The anisotropic conductive film exhibits favorable mounting conductive particle capture ratio, conduction reliability, number of linked particles, and insulating properties. In another aspect of the anisotropic conductive film of the present invention, conductive particles for anisotropic conductive connection are arranged in a single layer so that the embedding ratio in the first connection layer is 1% or more and 20% or less. For this reason, the first connection layer exhibits favorable stickiness and adhesion strength, and the anisotropic conductive film exhibits favorable conduction reliability, insulating properties (short circuit occurrence ratio), and mounting conductive particle capture ratio. Therefore, the anisotropic conductive film of the present invention is useful in anisotropic conductive connection of an electronic component such as an IC chip to a wiring substrate. The width of the wiring of such an electronic component has been decreased. When the present invention contributes to such technical advancement, the effects are particularly exerted.

### REFERENCE SIGNS LIST

1, 100 anisotropic conductive film
2 first connection layer
2X, 2Y region of first connection layer
3 second connection layer
4 conductive particle
5 third connection layer
30, 40 release film
20 first temporary connection layer
31 photopolymerizable resin layer
50 temporary anisotropic conductive film
La particle diameter of conductive particles
Lb depth of conductive particles embedded in first connection layer

1. An anisotropic conductive film having a first connection layer and a second connection layer formed on a surface of the first connection layer, wherein
the first connection layer is a photopolymerized resin layer,
the second connection layer is a thermo- or photo-cationically, anionically, or radically polymerizable resin layer, and
the first connection layer has conductive particles for anisotropic conductive connection that are arranged in a single layer on a surface on a side of the second connection layer, and the conductive particles are embedded in the first connection layer at an embedding ratio of 80% or more, or 1% or more and 20% or less.

2. The anisotropic conductive film according to claim 1, wherein the first connection layer is a photo-radically polymerized resin layer obtained by photo-radically polymerizing a photo-radically polymerizable resin layer containing an acrylate compound and a photo-radical polymerization initiator.

3. The anisotropic conductive film according to claim 2, wherein the first connection layer further contains an epoxy compound and a thermo- or photo-cationic or anionic polymerization initiator.

4. The anisotropic conductive film according to claim 1, wherein the second connection layer is a thermo- or photo-cationically or anionically polymerizable resin layer containing an epoxy compound and a thermo- or photo-cationic or anionic polymerization initiator or a thermo- or photo-radically polymerizable resin layer containing an acrylate compound and a thermo- or photo-radical polymerization initiator.

5. The anisotropic conductive film according to claim 4, wherein the second connection layer is a thermo- or photo-cationically or anionically polymerizable resin layer containing an epoxy compound and a thermo- or photo-cationic or anionic polymerization initiator and further contains an acrylate compound and a thermo- or photo-radical polymerization initiator.

6. The anisotropic conductive film according to claim 1, wherein a curing ratio of the first connection layer in a region between the conductive particle and an outermost surface of the first connection layer is lower than a curing ratio in a region between adjacent conductive particles.

7. The anisotropic conductive film according to claim 1, wherein a lowest melt viscosity of the first connection layer is higher than a lowest melt viscosity of the second connection layer.

8. A production method of the anisotropic conductive film according to claim 1, comprising the following steps (A) to (C):
Step (A)
a step of arranging conductive particles in a single layer on a photopolymerizable resin layer so that an embedding ratio of the conductive particles embedded in the first connection layer is 80% or more, or 1% or more and 20% or less;
Step (B)
a step of irradiating the photopolymerizable resin layer having the arranged conductive particles with ultraviolet light to cause a photopolymerization reaction, to thereby form the first connection layer in which the conductive particles are fixed on the surface; and
Step (C)
a step of forming the second connection layer that includes a thermo- or photo-cationically, anionically, or radically polymerizable resin layer on a surface of the first connection layer on a conductive particle side.

9. The production method according to claim 8, wherein the step (B) of irradiating with ultraviolet light is performed from the surface where the conductive particles are arranged in the photopolymerizable resin layer.

10. A production method of the anisotropic conductive film according to claim 1, comprising the following steps (AA) to (DD):
Step (AA)
a step of arranging conductive particles in a single layer on a photopolymerizable resin layer so that an embedding ratio of the conductive particles embedded in the first connection layer is 80% or more, or 1% or more and 20% or less;
Step (BB)
a step of irradiating the photopolymerizable resin layer having the arranged conductive particles with ultraviolet light to cause a photopolymerization reaction, to thereby form a first temporary connection layer in which the conductive particles are temporarily fixed on the surface;
Step (CC)
a step of forming the second connection layer that includes a thermo-cationically, anionically, or radically polymerizable resin layer on a surface of the first temporary connection layer on a conductive particle side; and
Step (DD)
a step of irradiating the first temporary connection layer with ultraviolet light from a second connection layer side and an opposite side thereof to cause a photopolymerization reaction, to thereby completely cure the first temporary connection layer to form the first connection layer.

11. The production method according to claim 10, wherein the step (BB) of irradiating with ultraviolet light is performed from the surface where the conductive particles are arranged in the photopolymerizable resin layer.

12. The production method according to claim 8, comprising, after the step (C), the following step (Z):
Step (Z)
a step of forming a third connection layer that includes a thermo- or photo-cationically, anionically, or radically polymerizable resin layer on a surface of the first connection layer opposite to the conductive particles.

13. The production method according to claim 8, comprising, before the step (A), the following step (a):
Step (a)
a step of forming a third connection layer that includes a thermo- or photo-cationically, anionically, or radically polymerizable resin layer on a surface of the photopolymerizable resin layer, and wherein
in the step (A), the conductive particles are arranged in a single layer on another surface of the photopolymerizable resin layer so that an embedding ratio of the conductive particles embedded is 80% or more, or 1% or more and 20% or less.

14. The production method according to claim 10, comprising, after the step (DD), the following step (Z):
Step (Z)
a step of forming a third connection layer that includes a thermo- or photo-cationically, anionically, or radically polymerizable resin layer on a surface of the first connection layer opposite to the conductive particles.

15. The production method according to claim 10, comprising, before the step (AA), the following step (a):
Step (a)
a step of forming a third connection layer that includes a thermo- or photo-cationically, anionically, or radically polymerizable resin layer on a surface of the photopolymerizable resin layer, and wherein
in the step (AA), the conductive particles are arranged in a single layer on another surface of the photopolymerizable resin layer so that an embedding ratio of the conductive particles embedded is 80% or more, or 1% or more and 20% or less.

16. A connection structure in which a first electronic component and a second electronic component are connected by anisotropic conductive connection through the anisotropic conductive film according to claim 1.
